(19) United States
(12) Patent Application Publication
(10) Pub. No.: US 2022/0026800 A1
(43) Pub. Date: Jan. 27, 2022

(54) IMPRINT APPARATUS, IMPRINTING METHOD, AND METHOD OF MANUFACTURING PRODUCT

(71) Applicant: CANON KABUSHIKI KAISHA, Tokyo (JP)

(72) Inventor: Hiroshi Sato, Utsunomiya-shi (JP)

(21) Appl. No.: 17/492,366

(22) Filed: Oct. 1, 2021

Related U.S. Application Data
(63) Continuation of application No. 15/571,484, filed on Nov. 2, 2017.

(30) Foreign Application Priority Data
May 13, 2015 (JP) 2015-098491

(51) Int. Cl. G03F 7/00; G03F 9/00; G03F 7/20

(52) U.S. Cl. CPC G03F 7/0002; G03F 7/7085; G03F 9/7042

(57) ABSTRACT

A forming method of forming an imprint material on a first substrate and a second substrate using a mold is provided. A first forming step of forming an imprint material on the first substrate held by a first substrate holding unit is performed. The second substrate held by a second substrate holding unit is measured. An imprint material on the second substrate held by the first substrate holding unit. A detecting step is performed to detect an imprint material formed on the first substrate held by the second substrate holding unit. The detecting step is performed in a state where the second forming step is performed, after the measuring step is performed in a state where the first forming step is performed.

### CROSS-REFERENCE TO RELATED APPLICATION

This application is a Continuation of co-pending U.S. patent application Ser. No. 15/571,484 filed Nov. 2, 2017; which is a National Phase Application of International Application PCT/JP2016/002271, filed May 9, 2016, which claims the benefit of Japanese Patent Application No. 2015-098491, filed May 13, 2015, which is hereby incorporated by reference herein in its entirety.

### TECHNICAL FIELD

The present invention relates to an imprint apparatus, an imprinting method, and a method of manufacturing a product.

### BACKGROUND ART

An imprinting technique is a technique for transferring a pattern formed on a mold to an imprinting material supplied to a substrate and is one suggested technique for manufacturing semiconductor devices, magnetic storage media, and optical components. In an imprint apparatus, an imprinting material (such as a photocurable resin) supplied to a substrate is brought into contact with a mold on which a pattern is formed, and the imprinting material is cured while being in contact with the mold. The substrate and the mold are separated and the mold is detached from the cured imprinting material. In this way, the pattern can be formed in (transferred to) the imprinting material on the substrate.

In such an imprint apparatus, the so-called die-by-die alignment method can be used for positioning (alignment) of the mold and the substrate. The die-by-die alignment method is for detecting a mark formed in the mold and a mark formed in the substrate in each area (shot region) on which the pattern is formed and for correcting the relative positions of the mold and the substrate. The marks used for positioning are detected by a detector (scope) provided in the imprint apparatus.

However, even when the pattern is formed on the substrate after positioning by the die-by-die alignment method, variations in the result of overlap occur among the shot regions. It is accordingly desirable to perform overlap inspection in many shot regions on the substrate. In view of this, PTL 1 discloses an imprint apparatus that performs overlap inspection by using an overlap inspecting mechanism disposed inside the imprint apparatus before a substrate on which a pattern has been formed is unloaded from the imprint apparatus.

In the imprint apparatus in PTL 1, however, after the pattern is formed on the substrate loaded into the imprint apparatus and the overlap inspection is finished, a substrate on which a subsequent imprint process is performed is loaded into the imprint apparatus. While the overlap inspection is being performed, the next substrate is not loaded into the imprint apparatus, and accordingly, the imprint apparatus cannot form the pattern on the next substrate.

### CITATION LIST

### Patent Literature

### [PTL 1]

### Japanese Patent Laid-Open No. 2009-88264

### SUMMARY OF INVENTION

The present invention provides an imprint apparatus for performing an imprint process such that an imprinting-material pattern is formed on a substrate by using a mold. The imprint apparatus includes a detector that detects the imprinting-material pattern formed on the substrate, and a controller that controls the imprint apparatus. The controller enables an imprinting step and a detecting step to be performed in parallel such that the imprinting-material pattern is formed on the substrate by the imprint process in the imprinting step and the imprinting-material pattern formed on a substrate that differs from the substrate on which the imprint process is being performed is detected by the detector in the detecting step.

Further features of the present invention will become apparent from the following description of exemplary embodiments with reference to the attached drawings.

### BRIEF DESCRIPTION OF DRAWINGS

FIG. 1 is a diagram of an imprint apparatus according to a first embodiment.

FIG. 2 is a diagram of a correction mechanism according to an embodiment of the present invention.

FIG. 3A is a diagram showing a state of an imprint process.

FIG. 3B is a diagram showing a state of the imprint process.

FIG. 3C is a diagram showing a state of the imprint process.

FIG. 4 is a sequence diagram of the first embodiment.

FIG. 5 is a diagram of the imprint apparatus according to the first embodiment.

FIG. 6 is a diagram of an imprint apparatus according to a second embodiment.

FIG. 7 is a sequence diagram of the second embodiment.

### DESCRIPTION OF EMBODIMENTS

Preferred embodiments of the present invention will hereinafter be described in detail with reference to the attached drawings. In the drawings, like symbols designate like components, and a duplicative description for these components is omitted.

### First Embodiment

### [Imprint Apparatus]

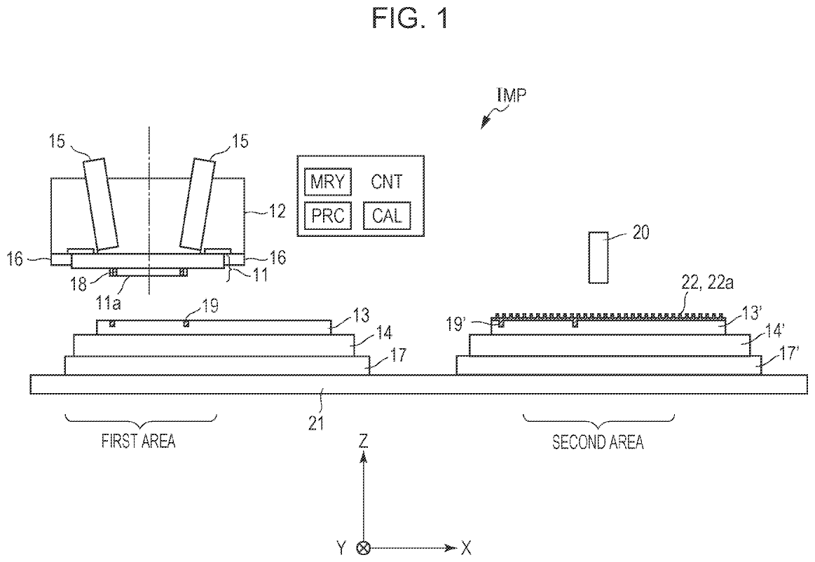

An imprint apparatus IMP according to a first embodiment will be described with reference to FIG. 1. As shown in FIG. 1, the imprint apparatus IMP is provided with a mold holding unit 12 (imprinting head) that holds a mold 11, a substrate holding unit 14 (substrate stage) that holds a substrate 13, and a detector 15 (alignment scope) that detects marks used for positioning. The imprint apparatus IMP may also be provided with a correction mechanism 16 that changes the shape of the mold 11 (pattern surface 11a) and a substrate driving unit 17 that holds and drives the substrate holding unit 14. The imprint apparatus IMP may further be provided with a base surface plate 21 on which the substrate driving unit 17 is placed, and a bridge surface plate that holds the mold holding unit 12. The marks used for positioning include a mold mark 18 formed in the mold 11 and a substrate mark 19 formed in the substrate 13. The imprint apparatus IMP according to the first embodiment includes, at a position apart from the mold holding unit 12, a detector 20, for use in inspection, which detects the state (defect) of a transferred pattern formed on the substrate. The detector 20, for use in inspection, can detect the mark formed in the substrate and an imprinting-material mark formed on the substrate in order to measure the relative positions of an underlying pattern and the transferred pattern (overlap measurement). The imprint apparatus IMP is also provided with a controller CNT that controls the action of imprinting. The imprint apparatus IMP may include an applicator (dispenser) that applies (supplies) an imprinting material to the substrate 13. The imprint apparatus IMP performs an imprint process such that the imprinting material on the substrate 13 is brought into contact with the mold 11 and an imprinting-material pattern is formed on the substrate 13.

The imprint apparatus IMP brings the imprinting material on the substrate 13 into contact with the mold 11 having the pattern surface 11a on which an uneven pattern is formed. The imprinting material is cured with the imprinting material being in contact with the mold. The gap between the mold 11 and the substrate 13 is widened to separate (detach) the mold 11 from the cured imprinting material. The imprint process is thus performed to form (transfer) the pattern in the imprinting material on the substrate 13. In the imprint apparatus IMP according to the first embodiment, a photocurable resin that is cured by ultraviolet radiation is used as the imprinting material.

The mold 11 has the pattern surface 11a on which a pattern with a three-dimensional shape (uneven shape) is formed. The uneven shape formed on the pattern surface 11a corresponds to the pattern to be transferred to the imprinting material on the substrate 13. The mold mark 18 is formed in the pattern surface 11a. The mold 11 is made of a material (such as quartz) that is transparent to ultraviolet rays, which cause the imprinting material on the substrate 13 to cure.

The mold holding unit 12 is a holding mechanism that holds the mold 11 and includes a mold chuck that holds the mold 11 by vacuum suction or electrostatic suction, a mold stage on which the mold chuck is placed, and a mold driving unit that drives the mold stage. The mold driving unit can move the mold stage (that is, the mold 11) in at least a Z-axis direction (direction in which the imprinting material on the substrate 13 is brought into contact with the mold 11, or imprinting direction). The mold driving unit may have a function that drives the mold stage not only in the Z-axis direction but also in an X-axis direction, a Y-axis direction, and a theta direction (rotation about the Z-axis).

Examples of the substrate 13 include a single-crystal silicon wafer, a silicon-on-insulator (SOI) wafer, and a glass substrate. The imprinting material is supplied to the substrate 13. The substrate 13 is provided with plural shot regions. In each shot region, the substrate mark 19 is formed. The shot regions described herein represent areas of the substrate 13 to which the pattern (pattern surface 11a) formed on the mold 11 is transferred.

The substrate holding unit 14 is a holding mechanism that holds the substrate 13 and includes a substrate chuck that holds the substrate 13 by vacuum suction or electrostatic suction. The substrate driving unit 17 is a driving mechanism that holds and drives the substrate chuck and includes a substrate stage on which the substrate holding unit 14 is placed. The substrate driving unit 17 can move the substrate stage (that is, the substrate 13) in at least the X-axis direction and the Y-axis direction (direction of a plane perpendicular to the direction in which the mold 11 is imprinted). The substrate driving unit 17 may have a function that drives the substrate stage not only in the X-axis direction and the Y-axis direction but also in the Z-axis direction and the theta direction (rotation about the Z-axis).

The detector 15 includes a scope that optically detects (observes) the mold mark 18 formed in the mold 11 and the substrate mark 19 formed in the substrate 13. The detector 15 need only be able to detect the relative positions of the mold mark 18 and the substrate mark 19. Accordingly, the detector 15 may include a scope having an optical system that simultaneously captures the images of the two marks, or a scope that detects signals, such as interference signals or moire pattern signals, including the information of the relative positions of the two marks. The detector 15 need not simultaneously detect the mold mark 18 and the substrate mark 19. For example, the detector 15 may detect the relative positions of the mold mark 18 and the substrate mark 19 by obtaining the relative positions of the mold mark 18 and the substrate mark 19 with respect to the surface of a sensor or a reference position that is located on the inside.

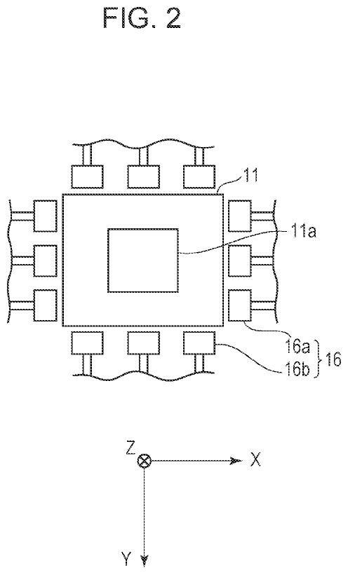

The correction mechanism 16 (deforming member) can change the shape of the pattern surface 11a by applying a force to the mold 11 from the direction (XY direction) parallel to the pattern surface 11a. As shown in FIG. 2, the correction mechanism 16 includes contact portions 16a that come into contact with side surfaces of the mold 11, actuators 16b that drive the contact portions 16a in the direction in which the contact portions 16a approach the corresponding pattern surfaces 11a and in the direction in which the contact portions 16a move away from the corresponding pattern surfaces 11a. The correction mechanism 16 may be a mechanism that changes the shape of the pattern surface 11a by heating the mold 11 while controlling the temperature of the mold 11.

The controller CNT includes a memory MRY that stores a program to control the imprint apparatus IMP, a processor PRC that executes the program stored in the memory MRY, and a calculator CAL that calculates the relative positions of the mold and the substrate by using the result of the detection by the detector 15. The controller CNT outputs signals to control the units of the imprint apparatus IMP in accordance with the executed program. The degree of misalignment between the mold 11 and the substrate 13 is calculated by the calculator CAL of controller CNT on the basis of the result of the detection of the mold mark 18 and the substrate mark 19 by the detector 15. The controller CNT receives the result of the calculation by the calculator CAL and outputs signals to drive the mold holding unit 12 or the substrate driving unit 17. The mold holding unit 12 or the substrate driving unit 17 is moved on the basis of the signals output from the controller CNT so that the relative positions of the mold 11 and the substrate 13 are changed for positioning of the mold 11 and the substrate 13. Both of the mold holding unit 12 and the substrate driving unit 17 may be driven simultaneously or in a serial order. When the imprint apparatus IMP forms the pattern, the controller CNT controls the degree to which the pattern surface 11a of the mold 11 is deformed by the correction mechanism 16.

### [Imprint Process]

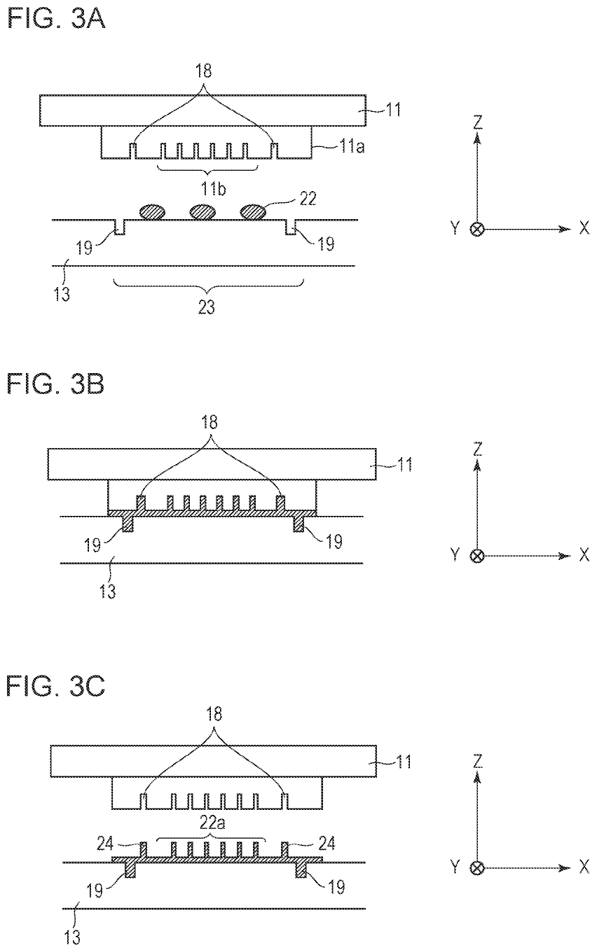

The imprint process will be described with reference to FIG. 3A to FIG. 3C. FIG. 3A to FIG. 3C show a state where the imprint apparatus IMP forms the desired pattern in the imprinting material on the substrate 13.

As shown in FIG. 3A, the imprint apparatus IMP adjusts the positions of the mold 11 and the substrate 13 in a state where an imprinting material 22 has been supplied to an area (shot region 23) on which the pattern is formed. The imprinting material 22 is typically very volatile. It is accordingly desirable to supply the imprinting material to a single shot region at one time. However, when the volatility of the imprinting material 22 is low, the imprint apparatus IMP may supply the imprinting material 22 to plural shot regions 23 at one time, or the substrate 13 to which the imprinting material 22 is applied in advance by using an external applicator may be loaded. In FIG. 3A, the detector 15 detects the mold mark 18 and the substrate mark 19 and obtains the relative positions of the mold 11 and the substrate 13 on the basis of the result of the detection. The pattern surface 11a of the mold 11 includes a pattern portion 11b (uneven structure) on which the pattern to be transferred to the substrate 13 is formed, other than the mold mark 18 for positioning.

As shown in FIG. 3B, the imprinting material 22 is brought into contact with the mold 11, and the pattern portion 11b is filled with the imprinting material. At this time, light (for example, visible light) used for detecting the marks passes through the imprinting material 22. For this reason, the substrate mark 19 can be measured when the mold 11 is in contact with the imprinting material. The mold 11 is made of a transparent material such as quartz, and, accordingly, the difference in refractive index between the mold 11 and the imprinting material is small. For this reason, when the uneven structure of the mold mark 18 is filled with the imprinting material, the measurement of the mold mark 18 may be impossible in some cases. In view of this, a material whose refractive index and transmittance are different from those of the mold 11 is applied (attached) to the mold mark 18, or the refractive index is changed by, for example, ion radiation. In this way, the detector 15 can detect the mold mark 18 and the substrate mark 19 in a state shown in FIG. 3B.

FIG. 3C shows a state where the mold 11 is detached (separated) from the cured imprinting material after the imprinting material is irradiated with ultraviolet rays. An imprinting-material pattern 22a corresponding to the pattern portion 11b is transferred to the substrate 13. A pattern corresponding to the mold mark 18 is also transferred to the substrate 13, and a transferred mark 24 is formed. The detection of the transferred mark 24 and the substrate mark 19 enables the measurement of the misalignment between each shot region and the imprinting-material pattern formed on the substrate (overlap inspection). The marks used for the measurement of the misalignment may be marks used for alignment or marks formed for overlap inspection. The transferred mark 24 and the substrate mark 19 are detected by using the detector 20, for use in inspection, as shown in FIG. 1. The relative positions of the transferred mark 24 and the underlying pattern are measured from the result of the detection. This measurement is referred to as overlay measurement or overlap inspection. The pattern can be formed on the shot regions on the substrate by repeating the imprint process in each shot region, as shown in FIG. 3A to FIG. 3C.

### [Sequence in Imprint Apparatus]

The imprint apparatus can perform an imprinting step and an inspecting step (detecting step) in parallel such that the pattern is formed on the substrate in the imprinting step and the formed pattern is inspected in the inspecting step. This will be described below. The imprint apparatus described in the first embodiment can measure the result of imprinting inside the imprint apparatus and provide feedback about the result of the measurement to a subsequent imprinting step.

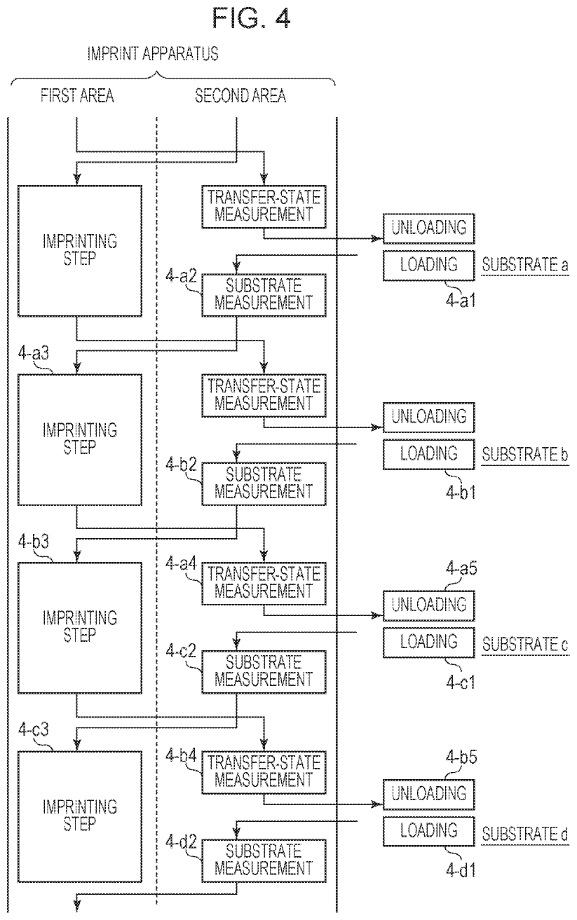

The imprint process according to the first embodiment will be described with reference to FIG. 1 and FIG. 4. FIG. 1 shows the imprint apparatus IMP, which forms the desired pattern in the imprinting material on the substrate 13. The imprint apparatus IMP in FIG. 1 includes the substrate holding unit 14 (first substrate holding unit) and a second substrate holding unit 14′, as different holding units. The substrate holding unit 14 and the second substrate holding unit 14′ respectively hold the substrate 13 and the substrate 13′, as different substrates. In FIG. 1, the substrate 13 is a substrate on which the pattern will be formed in the imprinting step. The substrate 13′ is a substrate on which the imprinting-material pattern (transferred mark) has been formed in the imprinting step. In the inspecting step, the substrate 13′ is inspected for a transfer state (state of the imprint process). Here, an area in which the pattern is formed on the substrate 13 held by the substrate holding unit 14 in the imprinting step is referred to as a first area, and an area in which the pattern formed on the substrate is chiefly inspected in the inspecting step is referred to as a second area. The first area is not limited to an area in which the mold holding unit 12 that holds the mold 11 is disposed. The first area includes an area of an XY plane on which the substrate holding unit 14 moves when the pattern is formed in the imprinting step. The second area is not limited to an area in which the detector 20, for use in the inspection of the pattern formed on the substrate, is disposed. The second area includes an area of the XY plane on which the substrate holding unit 14 moves in the inspecting step. When the inspecting step is performed without moving the substrate holding unit 14, the detector 20, for use in inspection, is moved. The second area may be an area of the XY plane on which the detector 20, for use in inspection, is moved. The first area and the second area are determined so as not to overlap each other.

FIG. 4 is a sequence diagram of the first embodiment. FIG. 4 shows substrate measurements, the imprinting steps, and transfer-state measurements that are continuously performed on plural substrates (substrates a to d). Part of the steps shown in FIG. 4 will now be described. The steps for the substrate (substrate b) shown in FIG. 4 will be described in sequence. The imprinting step may be regarded as a period from when the substrate holding unit 14 holds a substrate until the pattern is formed on the shot regions on the substrate by the imprint process. The inspecting step may be regarded as a period from when the second substrate holding unit 14′ holds a substrate on which the pattern has been formed in the imprinting step until the substrate is inspected for the transfer state and unloaded from the imprint apparatus.

In substrate loading in Step 4-b1, the substrate b is loaded from the outside of the imprint apparatus into the imprint apparatus. The loaded substrate b is held by the second substrate holding unit 14′. At this time, the imprinting material may be supplied to the substrate b in advance, or the imprinting material may be supplied to the substrate b inside the imprint apparatus.

In the substrate measurement (preliminary measurement) in Step 4-b2, preparations for the imprinting step are made. The substrate measurement in Step 4-b2 is performed in the second area of the imprint apparatus. The substrate measurement includes the detection of a notch or an orientation flat of the substrate b, position measurement of measuring the marks in the substrate, the inspection of the applied imprinting material and foreign material on the substrate surface, the measurement of the height position of the substrate surface, and the inspection of the amount of the applied imprinting material. After the substrate measurement is performed for the imprinting step, the substrate b is fed to the first area. At this time, the substrate holding unit 14 in the first area holds the substrate a. Accordingly, the substrate b is fed to the first area, when the imprinting step (Step 4-a3) has been performed on the substrate a, and the substrate a is fed to the second area. Plural transfer arms, or a transfer arm that can hold plural substrates may be used to switch the positions of the substrates.

In the imprinting step in Step 4-b3, the pattern on the mold 11 is transferred to the imprinting material on the substrate b. In the first area, the substrate measurement described for Step 4b-2, such as the inspection of the foreign material on the substrate surface or the measurement of the height position of the substrate surface, may be performed if necessary, in addition to the imprinting step. Although the imprint apparatus using the die-by-die alignment method is described in the embodiment, the imprint apparatus may use the global alignment method. In this case, marks on a substrate are typically measured by using a measurement scope disposed in the first area and the result of the detection is used to obtain the relationship of the relative position between the substrate and the mold. The substrate b on which the pattern has been formed in the imprinting step is fed to the second area. At this time, the second substrate holding unit 14′ in the second area holds the substrate c. Accordingly, the substrate b is fed to the second area, when the substrate measurement (Step 4c-2) has been performed on the substrate c, and the substrate c is fed to the first area.

In the transfer-state measurement in Step 4-b4, the state of the substrate b to which the pattern has been transferred in the imprinting step in Step 4-b3 is measured. The measurement of the state of the substrate to which the pattern has been transferred enables the transfer performance of the imprint apparatus to be estimated.

In the transfer-state measurement (inspecting step), the measurement of the relative positions of the transferred mark 24 and the substrate mark 19, as shown in FIG. 3A to FIG. 3C enables the measurement of the relative positions of each shot region and the corresponding imprinting-material pattern 22a. In an example of the measurement of the misalignment, both of the transferred mark 24 and the substrate mark 19 may be simultaneously measured by overlapping square patterns of different sizes, one of which is formed on the substrate and the other of which is transferred to the imprinting material (Box-In-Box measurement). These square patterns are often used in the overlap inspection. In addition, the marks used for alignment when the relative positions of the mold and the substrate are measured in the imprinting step may be used. The relative positions of each shot region and the corresponding imprinting-material pattern 22a may be measured by detecting the transferred mark 24 and the substrate mark 19 one by one by using the detector 20 for use in inspection. The relative positions may be obtained by forming the transferred mark 24 and the substrate mark 19 as lattice patterns and by using beats, diffracted light, or moire fringes that are produced when the lattice patterns overlap each other.

The transfer-state measurement may be the inspection of the presence or absence of a defect in the formed imprinting-material pattern 22a, or foreign material attached to the substrate. Various defects may occur in the imprinting-material pattern 22a formed in the imprinting step. Pattern defects include a chip of a pattern, collapse of an elevated pattern, and variation in the width or height of a transferred pattern. The defect in the imprinting-material pattern 22a may be repeatedly produced among the shot regions or the substrates. When the substrates are inspected by using a defect inspecting apparatus disposed outside the imprint apparatus, the time-lag of feedback about the above information occurs. Accordingly, transferring steps are performed under conditions in which the defect occurs, until the feedback is provided. For this reason, the inspecting step for the pattern defect is performed in the imprint apparatus to provide the feedback more quickly, resulting in a reduction in the occurrence of the defect. The result of the measurement of the pattern defect includes the size of the defect and defect distribution.

When foreign material attaches to the substrate, the mold may be damaged in the imprinting step. In the case where the inspecting step for foreign material reveals that the foreign material is attached to the substrate, it is necessary to check whether the mold 11 is damaged. For example, the mold 11 is inspected, by using a scope disposed inside the imprint apparatus, at a position in the mold 11 that corresponds to a position in the shot region at which the foreign material is detected, the mold 11 is unloaded from the imprint apparatus and cleaned, or the mold 11 is inspected by using a scope disposed outside the imprint apparatus. The result of the transfer-state measurement may be output to the outside of the imprint apparatus to precisely check the mold 11 outside the imprint apparatus.

The transfer-state measurement may be the inspection of a residual layer. In the imprinting step, when the imprinting material 22 on the substrate 13 is brought into contact with the mold 11, a layer of the imprinting material 22 is produced between elevated portions of the pattern portion 11b of the mold 11 and the substrate 13. This layer is referred to as the residual layer. The residual layer formed on the substrate after the imprinting step is preferably uniform. In general, the thickness of the residual layer is about ten to several tens of nanometers. Accordingly, a detector that can measure the thickness of the residual layer with high precision may be disposed in the second area. Ellipsometry, in which light is incident obliquely on matter to be measured and a change in polarization of the reflected light is examined, is a well-known method of measuring the thickness of matter with high precision.

The conditions of the imprinting step can be optimized from the result of the inspection of the pattern formed on the substrate. For example, the formation of an undesired pattern is caused presumably by the following factor: an insufficiently supplied imprinting material, a lack of the amount of emitted light to cure the imprinting material, improperly separating the mold from the cured imprinting material, or dirt on the mold. Failure that can be found from the result of the inspection and factors causing the failure are preferably investigated in advance. The cause of variation in transfer performance can be found in an early stage from the result of the inspection of the pattern, and feedback can accordingly be given to the conditions of the pattern formation.

A preferred example of the detector 20, for use in the inspection of the imprinting-material pattern, is a detector such as a microscope that inspects the pattern by using light without coming into contact with the pattern, for the inspection can be made without breaking the imprinting-material pattern. In the case where there is a pattern having a width corresponding to the resolution of the microscope and a pattern having a width thinner than the width corresponding to the resolution of the microscope, the result of the inspection may be obtained from the inspection of the pattern having the width corresponding to the resolution of the microscope, as a representative pattern. It is, however, difficult to observe a pattern having a width of several tens of nanometers by using a typical microscope because of the optical resolution limit of the microscope. The imprint apparatus may accordingly include a near-field optical microscope or an atomic force microscope (AFM), which can be used to observe smaller objects. The inspection of the pattern by using such an inspecting apparatus takes time, and it is accordingly desirable to measure the representative pattern in the inspection of the pattern. In the case where there is a cause for which the degree of failure of the transferred pattern increases in each imprint process such as dirt on the mold 11, inspecting the last shot region on which the pattern has been formed on the substrate means inspecting the shot region in which the degree of failure is at its maximum. A peripheral shot region (edge shot region) or a distinctive point may be selected as a representative point.

The transfer-state measurement includes the inspection of the presence or absence of the pattern on the substrate. In some cases, the substrate, on which the pattern should be formed in the imprinting step, includes a shot region on which no pattern is formed due to an error of the imprint apparatus. Accordingly, the imprint apparatus can determine whether the pattern is formed by the imprint process according to the observation of each shot region on the substrate subjected to the imprinting step. At this time, the determination is made on the basis of the result of the observation of the transferred imprinting-material pattern 22a or the detection of the transferred mark 24. The determination can also be made on the basis of signals produced due to the substrate mark 19 and the transferred mark 24 overlapping each other (presence or absence of moire pattern signals or other signals).

The observation of each transfer area edge enables the detection of whether the amount of the applied imprinting material is excessive or short. For example, when the imprinting material applied to the shot region leaks into the adjacent shot region, the amount of the applied imprinting material is excessive. When the shot region is not filled with the imprinting material, the amount of the applied imprinting material is short. The amount of the applied imprinting material, a position at which the imprinting material is applied, and the pattern of the application can be adjusted accordingly.

Thus, the result of the transfer-state measurement in Step 4-b4 is used when the optimal conditions of transfer are found by using the controller CNT inside the imprint apparatus. On the basis of the obtained information, the optimal conditions are found and parameters are replaced. The substrate c and the substrate d can thereby be imprinted under better transfer conditions, after the substrate b has been imprinted. For example, when the overlap inspection is performed in the transfer-state measurement, measured values are offset on the basis of a difference from the target value when the imprinting step is performed on the next substrate c and the next substrate d, thereby overlapping with higher precision can be achieved. The detection of the positions of the foreign material and the defect in each shot region enables investigation into whether failure occurs in each transferred pattern or is related to the position in the substrate. For example, when failure occurs in each transferred pattern, there is a high probability that the mold causes the failure. It is accordingly sufficient to clean the mold 11. When the defect and variation in the residual layer frequently occur in a certain shot region (for example, a peripheral shot region) on the substrate, the conditions of transfer in which the imprinting step is performed in the certain shot region on the substrate are changed. For example, the amount in which the imprinting material is supplied (applied) to the certain shot region is changed.

In substrate unloading in Step 4-b5, the substrate b (substrate 13) subjected to the transfer-state measurement in Step 4-b4 is unloaded from the imprint apparatus.

In the embodiment, after a substrate is subjected to the imprint process and measured, imprinting conditions are corrected to optimize the imprinting conditions for the next substrate, and a series of steps for the optimization has been described. The embodiment is not limited thereto. For example, in the first area, the pattern may be formed by imprinting on only some shot regions on the substrate, the result may be measured in the second area, and the pattern may be formed in the other shot regions after the conditions of transfer are changed (corrected). The above steps may be performed on a first substrate in a certain lot, and another substrate in the same lot may be imprinted after the conditions of transfer are changed on the basis of the result of the first substrate.

### [Parallel Operation of Imprinting Step and Transfer-State Measurement Step]

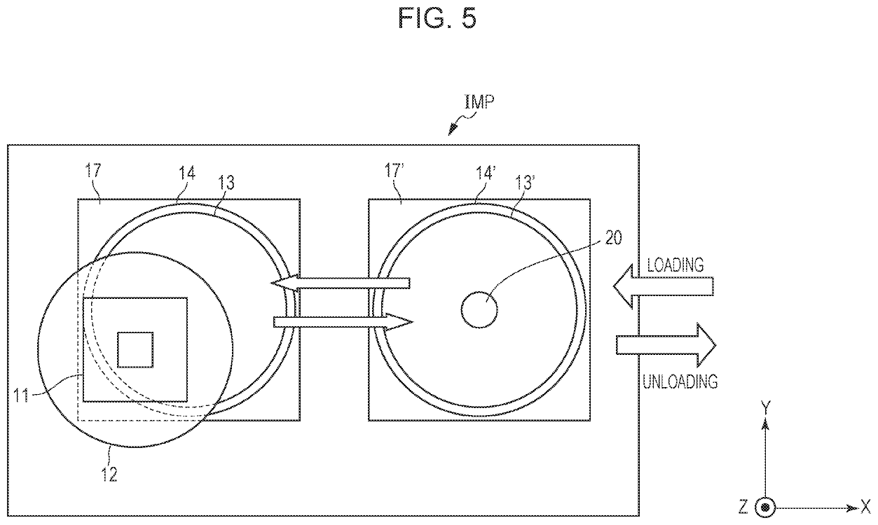

In the first embodiment, as shown in FIG. 5, the imprinting step in the first area and the transfer-state measurement in the second area are performed in parallel. FIG. 5 shows the imprint apparatus shown in FIG. 1 viewed in the Z-direction (direction in which the mold 11 and the substrate 13 are brought close to each other). In the imprint apparatus IMP according to the first embodiment, each substrate is loaded and unloaded at a common location. While the substrate b is subjected to the transfer-state measurement in Step 4-b4 in the second area, the substrate c, which is loaded into the imprint apparatus IMP after the substrate b is loaded, is subjected to the imprinting step in Step 4-c3. The imprint apparatus according to the first embodiment thus performs the transfer-state measurement step on the substrate b and the imprinting step on the substrate c in parallel. It is sufficient to perform at least part of the transfer-state measurement step and part of the imprinting step in parallel. The entire transfer-state measurement step and the entire imprinting step are not necessarily performed in parallel.

When the transfer-state measurement (Step 4-b4) performed in the second area is finished while the imprinting step (Step 4-c3) is being performed on the substrate c in the first area, the substrate b is unloaded from the imprint apparatus (substrate unloading in Step 4-b5). Then, a substrate d is loaded into the imprint apparatus (substrate loading in Step 4-d1). As shown in FIG. 5, in parallel with at least part of the imprinting step in Step 4-c3 performed in the first area, the substrate measurement in Step 4-d2 can be performed, in the second area, on the substrate loaded into the imprint apparatus. Accordingly, while the imprinting step in Step 4c-3 is being performed, in the first area, on the substrate c loaded into the imprint apparatus before the substrate d is loaded, the substrate loading in Step 4-d1 and the substrate measurement in Step 4-d2 may be performed, in the second area, on the substrate d. Thus, in the imprint apparatus according to the first embodiment, the substrate loading or the substrate measurement may be performed in parallel with at least part of the imprinting step.

Depending on the importance and effect of the result of the transfer-state measurement, the measurement method, the processing method, and the timing with which the result is reflected may be changed. It is thought that the defect of the transferred pattern and the foreign material on the substrate are caused by foreign material attached to the mold. In this case, the continued use of the mold to which the foreign material is attached may damage the mold, and, accordingly, the foreign material attached to the mold is preferably removed as soon as possible.

For example, when the substrate is loaded onto the second substrate holding unit, the measurement is first performed in the representative shot region on which the last pattern or a second-half pattern, among the patterns formed on the substrate, has been formed. When the defect or foreign material that is caused by foreign material attached to the mold is detected, the imprinting step at the first substrate holding unit is stopped. After the imprinting step is stopped, the mold may be replaced with a new one, or the mold may be subjected to a cleaning step. In this way, to prevent the mold from being damaged, action can be taken before the imprinting step is performed on the next substrate in the first area (before the pattern is formed) at the earliest, or in the early stage of the imprinting step.

Items that are distinguishable on the basis of the measurement performed in a single shot region can be distinguished from the result of the transfer-state measurement at the second substrate holding unit before the imprinting step is performed on the next substrate. The items to be distinguished include, for example, the precision of overlay, a leak of the imprinting material, and a greatly collapsed pattern, in addition to the defect and the foreign material.

In the case where similar pattern defects or collapsed patterns occur in the shot regions, there is a high probability that the pattern defects or the collapsed patterns repeatedly occur. For example, when the substrate subjected to the imprinting step is loaded onto the second substrate holding unit, the transfer-state measurement of the pattern formed on the substrate is performed in the representative shot region. The result of the measurement is used to determine whether the defect (repeated defect) occurs at the same position in each shot region. The probability of the occurrence of failure typically increases as the number of times the imprinting step has been performed increases. The representative shot region is preferably selected from the shot regions on which the pattern is formed in the second half of the imprinting steps.

The repeated defect will presumably occur again. Accordingly, when the repeated defect is found, the failure in the shot region is prevented from occurring again by carrying out the cleaning of the mold, the optimization of the application pattern of the imprinting material, the adjustment of time for filling, or the optimization of conditions such as imprinting conditions for the substrate and the mold. In this way, action can be taken before the imprinting step is performed on the next substrate in the first area at the earliest, or in the early stage of the imprinting step.

Items that are distinguishable on the basis of the observation of variation in the representative shot region can be distinguished from the result of the transfer-state measurement at the second substrate holding unit, and feedback can be given more quickly to the imprinting step that will be performed on the next substrate. For example, the items include overlay, the shapes of the shot regions, and the measurement of the residual layer, in addition to the above repeated defect. In the transfer-state measurement, the distribution of the precision of overlap can be measured by performing the overlap inspection of the underlying pattern and the transferred pattern that are formed on the substrate.

In some cases, the amount of correction of the shapes of the shot regions on the substrate is obtained for each shot region in advance, and the correction is made before die-by-die measurement. When the correction is made in each imprinting step by using the result of the measurement performed in each shot region (for example, the correction is made by applying a pressure to the mold), the correction of each shape takes time, and the imprinting step in each shot region accordingly takes time. This leads to a reduction in productivity. Accordingly, the correction is often made on the basis of the shape of each shot region that is known (obtained) in advance, before the die-by-die measurement.

The use of the result of actual imprinting enables the correction to be more precisely performed. In this way, feedback can be given to subsequent imprinting on the substrate on the basis of the result of the measurement performed in all of the shot regions. The shot region in which failure occurs can be assigned as an area whose information is sent to a subsequent step or an area that will be more precisely inspected. The inspection is not limited to the overlap inspection, and the residual layer may be measured to obtain the distribution thereof in a plane of the substrate.

Products in the same lot, which are typically manufactured in the same manufacturing process, have substantially the same structure. Accordingly, when some substrates are measured at identical positions in the substrates, a difference in values measured at the identical positions can be regarded as an abnormal value.

For items that are distinguishable on the basis of the measurement performed in all of the shot regions, the result of the measurement can be reflected in the imprinting step more quickly than in the case where measurement is performed in the shot regions by using a dedicated device disposed outside the imprint apparatus. For example, after the transfer-state measurement is performed, the result can be used in the imprinting step that will be performed on the substrate after the next substrate. Furthermore, after the transfer-state measurement is performed, the result can be used in the imprinting step while the imprinting step is being performed on the next substrate, if acceptable.

Thus, the transfer-state measurement performed in the imprint apparatus enables the result of the measurement to be reflected more quickly than in the case of the related art, in which the result of measurement performed in a dedicated device disposed outside the imprint apparatus is reflected. The occurrence of the defect can thereby be reduced.

In the imprint apparatus according to the first embodiment as described above, the imprinting step in the first area and the transfer-state measurement in the second area are performed in parallel; accordingly, the pattern formation and the inspection of the substrate on which the pattern has been formed can be performed without reducing productivity.

### Second Embodiment

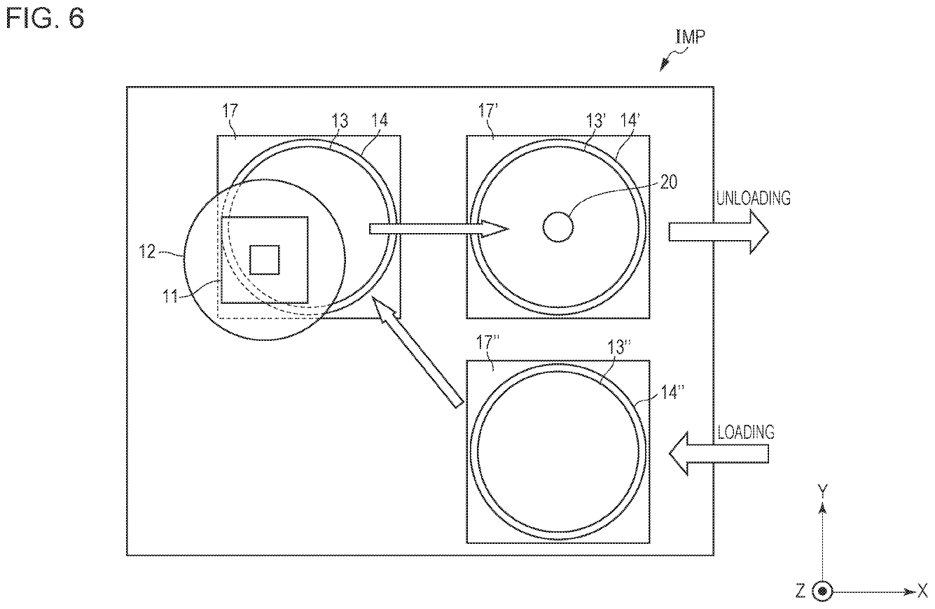

FIG. 6 shows an imprint apparatus according to a second embodiment. The imprint apparatus according to the second embodiment includes a third substrate holding unit 14″ that holds a substrate 13″ loaded into the imprint apparatus. In the imprint apparatus according to the second embodiment, a location at which the substrate is loaded differs from a location at which the substrate is unloaded, and the substrate measurement and the transfer-state measurement are performed in different areas. The substrate measurement is performed on the substrate 13″ held by the third substrate holding unit 14″, which differs from the substrate holding unit 14 and the second substrate holding unit 14′.

The position and the orientation of the substrate are corrected on the basis of the result of the substrate measurement, and the substrate is conveyed to and re-held by the substrate holding unit 14. Then, in the case where shot regions are formed in the substrate, global alignment measurement may be performed in the first area to obtain the positions of the shot regions on the substrate. In addition to the global alignment measurement, the die-by-die alignment measurement is performed to measure the relative positions of the mold mark 18 and the substrate mark 19 for positioning of the mold and the substrate.

In the global alignment measurement, marks formed in some shot regions (sample shot regions) on the substrate 13 held by the substrate holding unit 14 are detected, and, through statistical operation of the result of the detection, the positions (matrix information) of the shot regions on the substrate are obtained. For this reason, the preliminary measurement is preferably performed on the substrate held by the third substrate holding unit 14″ with such precision that enables the detection of the marks formed in the sample shot regions. In the imprint apparatus according to the second embodiment, while the substrate is held by the third substrate holding unit 14″, the marks formed in the shot regions may be detected to obtain the matrix information of the shot regions. Accordingly, the imprint apparatus according to the second embodiment may include a detector that detects the marks on the substrate 13″ held by the third substrate holding unit 14″ in advance.

In the second embodiment, an area of the third substrate holding unit 14″, which holds the substrate loaded into the imprint apparatus, is referred to as a third area. The third area includes an area in which the third substrate holding unit 14″ moves for the substrate measurement (preliminary measurement). The third area can be determined so as not to overlap the first area and the second area.

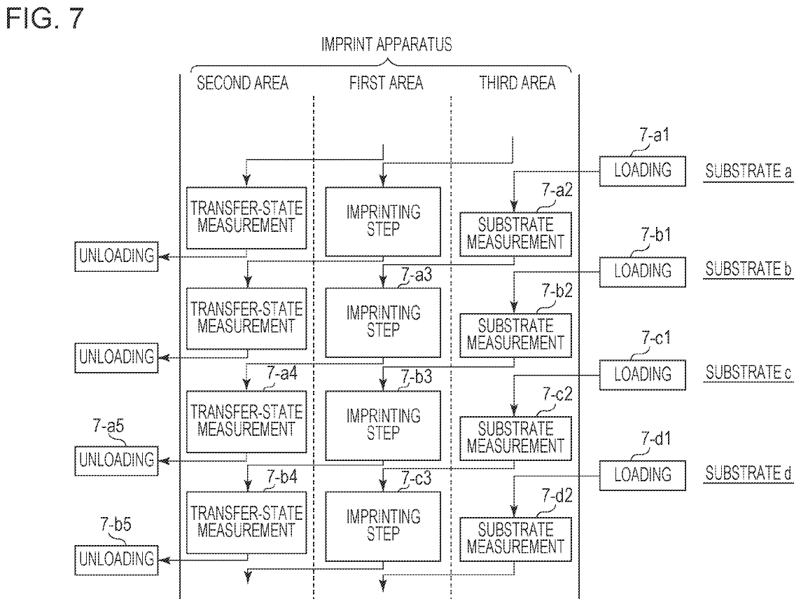

FIG. 7 is a sequence diagram of the second embodiment. FIG. 7 shows the substrate measurements, the imprinting steps, and the transfer-state measurements that are continuously performed on plural substrates (substrates a to d). Part of the steps performed on the substrate b shown in FIG. 7 will now be described.

In Step 7-b1, the substrate b (substrate 13) is loaded into the imprint apparatus. The loaded substrate b is held by the third substrate holding unit 14″.

In Step 7-b2, the substrate measurement is performed on the substrate b. The substrate measurement in Step 7-b2 is performed in the third area of the imprint apparatus. After the substrate measurement is performed for the imprinting step, the substrate b is fed to the first area. At this time, the substrate holding unit 14 in the first area holds the substrate a. Accordingly, the substrate b is fed to the first area, when the imprinting step (Step 7-a3) has been performed on the substrate a, and the substrate a is fed to the second area. As shown in FIG. 7, in the case where the time required for the substrate measurement is shorter than the time required for the imprinting step, the substrate 13 is left in the third area until the imprinting step is finished.

In Step 7-b3, the imprinting step is performed such that the imprinting-material pattern is formed on the substrate b by using the mold 11. At this time, the transfer-state measurement (Step 7-a4) is performed on the substrate a fed to the second area in parallel with the imprinting step (Step 7-b3). The substrate measurement (Step 7-c2) may be performed on the substrate c fed to the third area in parallel with the imprinting step (Step 7-b3). The substrate b on which the pattern has been formed in the imprinting step is fed to the second area.

In Step 7-b4, the transfer-state measurement is performed on the substrate b to which the pattern has been transferred in the imprinting step in Step 7-b3.

Thus, the imprint apparatus according to the second embodiment includes the three substrate holding units. Accordingly, while the imprinting step (Step 7-b3) is being performed on the substrate b, the transfer-state measurement (Step 7-a4) can be performed on the substrate a and the substrate measurement (Step 7-c2) can be performed on the substrate c. In the imprint apparatus according to the second embodiment, the transfer-state measurement (inspecting step) and the substrate measurement are performed in parallel with the imprinting step in the first area. This enables the pattern formation, the inspection of the substrate on which the pattern has been formed, and the preliminary measurement of the substrate to be performed without reducing productivity.

### Other Embodiments

In the first embodiment, the substrate 13 and the substrate 13′ are conveyed between the substrate holding unit 14 disposed in the first area and the second substrate holding unit 14′ disposed in the second area by using a conveying mechanism not shown, and are re-held by the substrate holding unit 14 or the second substrate holding unit 14′, as described above. However, when the substrate is re-held after being conveyed to the substrate holding mechanism, the result of the measurement performed in the second area, which is desirably used subsequently in the first area, may differ from the result in the first area. In this case, the positions of the substrate holding unit 14 and the second substrate holding unit 14′ may be switched while the substrate holding unit 14 holds the substrate 13 and the second substrate holding unit 14′ holds the substrate 13′. In this case, since the substrate holding units may be misaligned, after the positions of the substrate holding units are switched, marks formed in the substrate holding units and marks on the substrate are detected to correct the misalignment caused when the positions of the substrate holding units are switched. In the second embodiment, the third substrate holding unit 14″ may be switched in position while holding the substrate 13″.

In another embodiment, the substrate holding unit 14 may be moved together with the driving unit 17 while holding the substrate 13. In the embodiment, the second substrate holding unit 14′ is moved together with the driving unit 17′ while holding the substrate 13′ to switch the positions of the first area and the second area, and imprinting is performed. When the pattern is formed in the imprinting step by using the result of the measurement by the detector 20 for use in inspection, the substrate 13 and the substrate 13′ may be conveyed and re-held. The misalignment, however, may occur when the substrates are re-held, as described above. When the positions of the substrates are switched together with the driving units, reference marks formed in each substrate holding unit and marks on each substrate are measured, or the amount in which each substrate holding unit is driven is precisely measured, thereby allowing the result of the global alignment measurement performed in the second area to be used in the first area. In the second embodiment, the third substrate holding unit 14″ may be moved together with a driving unit while holding the substrate 13″.

In the embodiments, the result of the measurement performed in the second area is used for the transfer conditions when the imprinting step is performed on another substrate inside the imprint apparatus, as described above. In the imprint apparatuses according to the embodiments of the present invention, the result of the measurement of the defect and the residual layer that is obtained in the imprint apparatuses can be output to the outside of the imprint apparatus to use the result in an external inspecting apparatus or in a subsequent step that is performed outside the imprint apparatuses.

In the embodiments, the transferred mark 24 is transferred as a mark corresponding to the mold mark 18 to the substrate, as described above. The transferred mark 24, however, does not necessarily correspond to the mold mark 18. A transferred mark 24′ that differs from the transferred mark 24 may be formed on the substrate to perform the overlap inspection. In addition, a substrate mark 19′ that differs from the substrate mark 19 may be formed to perform the overlap inspection. The overlap inspection can be performed by using the transferred mark 24′ and the substrate mark 19′. Alternatively, no mark for the measurement may be formed, and a pattern formed on the substrate for a device and the transferred imprinting-material pattern 22a may be detected to measure the relative positions of these patterns.

In the embodiments, a photocurable resin that is cured by ultraviolet radiation is used as the imprinting material, as described above. The embodiments, however, are not limited to ultraviolet rays, and a photocurable resin that is cured by radiation of light with wavelengths other than ultraviolet wavelengths may be used. The method of curing the imprinting material is not limited to photocuring, and a thermosetting manner in which the imprinting material is cured by heat is also acceptable.

In the embodiments, the imprint apparatus IMP is described as a lithography apparatus for use in manufacturing processes of semiconductor devices. The present invention, however, is not limited to the imprint apparatus IMP. A lithography apparatus, such as an exposure apparatus or an electron beam lithography system that uses a plate on which a pattern is formed and exposes a substrate to light, is also acceptable. For the exposure apparatus that transfers the pattern formed on the plate (such as a reticle) to the substrate (such as wafer or glass plate that includes a resist layer formed on a surface thereof) through a projection optical system, a pattern (overlap mark) formed in the resist layer is detected (observed) after the exposure. A photosensitive resin (resist latent image) that enables an exposed portion thereof to be optically observed has been developed. The use of this photosensitive resin enables the transferred pattern to be observed in the exposure apparatus. Accordingly, before the exposed substrate is unloaded from the exposure apparatus, the transfer-state measurement can be performed in parallel with the exposure of the next substrate. The exposure apparatus may include a mechanism of heating the substrate, if necessary for the observation of the resist latent image.

### [Device Manufacturing Method]

A method of manufacturing a device (semiconductor integrated circuit device, liquid crystal display device, or another device) as a product includes a step of forming a pattern on a substrate (wafer, glass plate, or film substrate) by using the above imprint apparatus. The manufacturing method may include a step of etching the substrate on which the pattern has been formed. In the case where another product such as a patterned medium (recording medium) or an optical element is manufactured, the manufacturing method may include a step of processing the substrate on which the pattern has been formed, instead of etching. A method of manufacturing a product according to an embodiment is advantageous to at least one of the property, quality, productivity, and production cost of the product compared with existing methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A forming method of forming an imprint material on a first substrate and a second substrate using a mold, the forming method comprising:
a first forming step of forming an imprint material on the first substrate held by a first substrate holding unit;
a measuring step of measuring the second substrate held by a second substrate holding unit;
a second forming step of forming an imprint material on the second substrate held by the first substrate holding unit; and
a detecting step of detecting an imprint material formed on the first substrate held by the second substrate holding unit,
wherein the detecting step is performed in a state where the second forming step is performed, after the measuring step is performed in a state where the first forming step is performed.

2. The forming method according to claim 1, wherein a state of the imprint material formed on the first substrate is inspected by detecting the imprint material formed on the first substrate in the detecting step.

3. The forming method according to claim 1, wherein a relative position of a mark of the imprint material formed on the first substrate and a mark formed on the first substrate is measured by detecting the mark of the imprint material formed on the first substrate and the mark formed on the first substrate in the detecting step.

4. The forming method according to claim 1, wherein presence or absence of a foreign substance on the first substrate is detected by detecting the imprint material formed on the first substrate in the detecting step.

5. The forming method according to claim 1, wherein a thickness of a residual film of the imprint material on the first substrate is detected by detecting the imprint material formed on the first substrate in the detecting step.

6. The forming method according to claim 5, wherein a supply amount of the imprint material supplied onto the first substrate is obtained based on the thickness of the residual film of the imprint material on the first substrate in the detecting step.

7. The forming method according to claim 1, wherein at least one of measuring a notch, an orientation flat, or a mark of the second substrate, inspecting a foreign substance on the second substrate, measuring a height of the second substrate, and inspecting an amount of the imprint material supplied onto the second substrate is performed in the measuring step.

8. A forming method of forming an imprint material on a first substrate and a second substrate using a mold, the forming method comprising:
a first forming step of forming an imprint material on the first substrate held by a first substrate holding unit;
a measuring step of measuring the second substrate held by a second substrate holding unit;
an arranging step of replacing the first substrate holding unit configured to hold the first substrate and the second substrate holding unit configured to hold the second substrate with each other and arranging the first substrate holding unit and the second substrate holding unit;
a second forming step of forming an imprint material on the second substrate held by the second substrate holding unit; and
a detecting step of detecting an imprint material formed on the first substrate held by the first substrate holding unit,
wherein the arranging step is performed after the measuring step is performed in a state where the first forming step is performed, and the detecting step is performed in a state where the second forming step is performed after the arranging step is performed.

9. The forming method according to claim 8, wherein a state of the imprint material formed on the first substrate is inspected by detecting the imprint material formed on the first substrate in the detecting step.

10. The forming method according to claim 8, wherein a relative position of a mark of the imprint material formed on the first substrate and a mark formed on the first substrate is measured by detecting the mark of the imprint material formed on the first substrate and the mark formed on the first substrate in the detecting step.

11. The forming method according to claim 8, wherein presence or absence of a foreign substance on the first substrate is detected by detecting the imprint material formed on the first substrate in the detecting step.

12. The forming method according to claim 8, wherein a thickness of a residual film of the imprint material on the first substrate is detected by detecting the imprint material formed on the first substrate in the detecting step.

13. The forming method according to claim 12, wherein a supply amount of the imprint material supplied onto the first substrate is obtained based on the thickness of the residual film of the imprint material on the first substrate in the detecting step.

14. The forming method according to claim 8, wherein at least one of measuring a notch, an orientation flat, or a mark of the second substrate, inspecting a foreign substance on the second substrate, measuring a height of the second substrate, and inspecting an amount of the imprint material supplied onto the second substrate is performed in the measuring step.

15. A method of manufacturing an article, the method comprising:
a forming step of forming an imprint material on a first substrate and a second substrate using a mold;
a processing step of processing the first substrate and the second substrate on which the imprint material is formed in the forming step; and
a manufacturing step pf manufacturing an article from the first substrate and the second substrate processed in the processing step,
wherein the forming step includes:
a first forming step of forming an imprint material on the first substrate held by a first substrate holding unit;
a measuring step of measuring the second substrate held by a second substrate holding unit;
a second forming step of forming an imprint material on the second substrate held by the first substrate holding unit; and
a detecting step of detecting an imprint material formed on the first substrate held by the second substrate holding unit, and
wherein the detecting step is performed in a state where the second forming step is performed, after the measuring step is performed in a state where the first forming step is performed.

16. A method of manufacturing an article, the method comprising:
a forming step of forming an imprint material on a first substrate and a second substrate using a mold;
a processing step of processing the first substrate and the second substrate on which the imprint material is formed in the forming step; and
a manufacturing step pf manufacturing an article from the first substrate and the second substrate processed in the processing step,
wherein the forming step includes:
a first forming step of forming an imprint material on the first substrate held by a first substrate holding unit;
a measuring step of measuring the second substrate held by a second substrate holding unit;
an arranging step of replacing the first substrate holding unit configured to hold the first substrate and the second substrate holding unit configured to hold the second substrate with each other and arranging the first substrate holding unit and the second substrate holding unit;
a second forming step of forming an imprint material on the second substrate held by the second substrate holding unit; and
a detecting step of detecting an imprint material formed on the first substrate held by the first substrate holding unit, and
wherein the arranging step is performed after the measuring step is performed in a state where the first forming step is performed, and the detecting step is performed in a state where the second forming step is performed after the arranging step is performed.
